(19) United States
(12) Patent Application Publication
(10) Pub. No.: US 2026/0011560 A1
(43) Pub. Date: Jan. 8, 2026

(54) PALLADIUM COBALT OXIDE THIN FILM, DELAFOSSITE-TYPE OXIDE THIN FILM, SCHOTTKY ELECTRODE HAVING DELAFOSSITE-TYPE OXIDE THIN FILM, METHOD FOR PRODUCING PALLADIUM COBALT OXIDE THIN FILM, AND METHOD FOR PRODUCING DELAFOSSITE-TYPE OXIDE THIN FILM

(71) Applicants: National Institute for Materials Science, Tsukuba-shi, Ibaraki (JP); TANAKA KIKINZOKU KOGYO K.K., Chiyoda-ku, Tokyo (JP)

(72) Inventors: Takayuki HARADA, Tsukuba-shi, Ibaraki (JP); Yasushi MASAHIRO, Chiyoda-ku, Tokyo (JP)

(73) Assignees: National Institute for Materials Science, Tsukuba-shi, Ibaraki (JP); TANAKA PRECIOUS METAL TECHNOLOGIES Co., Ltd., Chuo-ku, Tokyo (JP)

(21) Appl. No.: 18/992,294

(22) PCT Filed: Mar. 27, 2023
(86) PCT No.: PCT/JP2023/012315

§ 371 Date: Jan. 8, 2025

(30) Foreign Application Priority Data
Jul. 11, 2022 (JP) 2022-111428

(51) Int. Cl. H01L 21/285; C23C 14/08; C23C 14/34; C23C 14/54; C23C 14/58; H01L 21/321; H10D 64/64

(52) U.S. Cl. CPC H01L 21/28506; C23C 14/08; C23C 14/3414; C23C 14/541; C23C 14/5806; H01L 21/321; H10D 64/64

(57) ABSTRACT

A palladium cobalt oxide thin film, a delafossite-type oxide thin film, a Schottky electrode having a delafossite-type oxide thin film, a method for producing a palladium cobalt oxide thin film, and a method for producing a delafossite-type oxide thin film are provided. In the palladium cobalt oxide thin film, the crystal grain size in the film is 100 nm or more and 500 nm or less, the thickness is greater than the critical film thickness, and the roughness value in the thickness direction is 4 nm or less.

### TECHNICAL FIELD

The present disclosure relates to a palladium cobalt oxide thin film, a delafossite-type oxide thin film, a Schottky electrode having a delafossite-type oxide thin film, a method for producing a palladium cobalt oxide thin film, and a method for producing a delafossite-type oxide thin film.

### BACKGROUND

Power devices (also referred to as power semiconductors, power elements, or power semiconductor elements) used in power converters such as inverters and converters are witnessing growing demand partly due to the rise in the use of electric vehicles (EVs), as disclosed in WO 2020/090491 A (PTL 1), for example. As an oxide for power devices, for example, gallium oxide is known.

NPL 1 discloses palladium cobalt oxide (PdCoO₂) having a delafossite-type crystal structure, as a PdCoO₂ ultrathin film with a high electrical conductivity for transparent electrodes. In NPL 1, PdCoO₂ thin films are produced by pulsed-laser deposition (PLD). As a specific example, a PdCoO₂ thin film was produced on an Al₂O₃ substrate under conditions of a substrate temperature of 700° C. and an oxygen partial pressure of 100 mTorr by alternately irradiating a PdCoO₂ polycrystalline target and a Pd—PdO mixed-phase target with a KrF excimer laser. An atomic force microscopy (AFM) topographic image of the PdCoO₂ thin film produced by pulsed-laser deposition is also shown in NPL 1. The AFM topographic image shows that the width of the PdCoO₂ crystals in the film is as small as about 100 nm, the crystal height is about 3 nm, and the roughness value (peak top difference) on the thin film surface in the thickness direction (height direction) is about 4 nm. Here, when a crystal has a triangular cross-section, for example, the “width” of a crystal refers to the length of a line drawn perpendicularly from a vertex to the opposite side. The shape of PdCoO₂ crystals in this film is triangular.

NPL 2 also discloses a PdCoO₂ thin film produced by pulsed-laser deposition. It is pointed out in NPL 2 that the resistivity of the PdCoO₂ thin film is higher than that of a single crystal of PdCoO₂, which is attributable to grain boundary scattering and is a factor different from temperature dependence. It is also pointed out that not forming grain boundaries is difficult in the production of heteroepitaxial films of PdCoO₂, posing technical limitations in the thin film technology for exploring the high electrical conductivity of PdCoO₂ in large-area prototypes.

NPL 3 discloses a case where a Schottky barrier as high as 1.8 eV was achieved in a PdCoO₂ thin film. The PdCoO₂ thin film is produced by pulsed-laser deposition. NPL 3 indicates that because of the naturally formed electric dipoles with a polar layered structure at the interface between PdCoO₂ and a thermally stable oxide, such as the interface between PdCoO₂ and β-Ga₂O₃, enabling current rectification with a large on/off ratio approaching the order of 10⁸ even in high-temperature environments, such as 350° C., for example. NPL 3 also discloses that the high-temperature operation of semiconductor devices is widely demanded for switching/sensing purposes in automobiles, plants, and aerospace applications.

### CITATION LIST

### Patent Literature

PTL 1: WO 2020/090491 A1

### Non-Patent Literature

NPL 1: Highly conductive PdCoO₂ ultrathin films for transparent electrodes, Harada et al., APL Mater 6, 046107 (2018)
NPL 2: Large thermopower anisotropy in PdCoO₂ thin films, Yordanov et al., Phys. Rev. Mater. 3, 085403 (2019)
NPL 3: Electric dipole effect in PdCoO₂/β-Ga₂O₃ Schottky diodes for high-temperature operation, Harada et al., Science Advances 5, eaax5733 (2019)

### SUMMARY

### Technical Problem

Since gallium oxide, for example, has a large band gap and high dielectric breakdown field, as well as a high thermal stability and excellent chemical resistance, it is an excellent semiconductor for power devices and is be expected to experience growing demand in power device applications. However, conventionally-used Schottky electrodes made of platinum have a relatively low Schottky barrier, for example, and their heat resistance and reliability (breakdown voltage) are insufficient in applications that use superior semiconductors for power devices, such as those using gallium oxide, where high output is required, for example.

In the meantime, delafossite-type oxides such as palladium cobalt oxide (PdCoO₂), palladium chromium oxide (PdCrO₂), palladium rhodium oxide (PdRhO₂), or platinum cobalt oxide (PtCoO₂) exhibit high electrical conductivity comparable to that of elemental metals such as gold, silver, and copper despite being oxides. They are expected to be employed as excellent Schottky electrodes for power devices such as those using gallium oxide. For example, with regard to the electrical conductivity, the electrical resistivity (μ⋅cm) of bulk single crystalline delafossite-type oxides (in the ab-plane at 300K) is 2.6, 8.2, 9.2, and 2.1 for palladium cobalt oxide, palladium chromium oxide, palladium rhodium oxide, and platinum cobalt oxide, respectively. It is generally necessary to deposit electrode materials as thin films in semiconductor devices, and there is room for improvement in the methods of producing these delafossite-type oxides such as palladium cobalt oxide to fully exploit their performance in thin film form. Therefore, there is a need to provide delafossite-type oxide thin films, such as palladium cobalt oxide thin films, that can be employed for applications such as Schottky electrodes in power devices, for example.

The present disclosure has been conceived of in view of the above circumstances, and an object thereof is to provide a palladium cobalt oxide thin film, a delafossite-type oxide thin film, a Schottky electrode having a delafossite-type oxide thin film, a method for producing a palladium cobalt oxide thin film, and a method for producing a delafossite-type oxide thin film.

### Solution to Problem

In a palladium cobalt oxide thin film according to the present disclosure to achieve the above object, a crystal grain size in the film is 100 nm or more and 1000 nm or less, a film thickness is greater than a critical film thickness, and a roughness value in a thickness direction is 4 nm or less.

A delafossite-type oxide thin film according to the present disclosure to achieve the above object is a delafossite-type oxide thin film comprising palladium chromium oxide (PdCrO₂), palladium rhodium oxide (PdRhO₂), or platinum cobalt oxide (PtCoO₂) having a delafossite-type crystal structure,
wherein a crystal width in the film is 100 nm or more and 1000 nm or less,
a film thickness is greater than a critical film thickness, and a roughness value in a thickness direction is 4 nm or less.

A Schottky electrode according to the present disclosure to achieve the above object comprises:
a delafossite-type oxide thin film of palladium cobalt oxide (PdCoO₂), palladium chromium oxide (PdCrO₂), palladium rhodium oxide (PdRhO₂), or platinum cobalt oxide (PtCoO₂), wherein a crystal grain size in the film is 100 nm or more and 1000 nm or less, a film thickness is greater than a critical film thickness, and a roughness value in a thickness direction is 4 nm or less.

A method for producing a palladium cobalt oxide thin film according to the present disclosure to achieve the above object comprises:
a target production step of firing a mixed powder of palladium chloride (PdCl₂), palladium (Pd), and lithium cobalt oxide (LiCoO₂) to produce a target of palladium cobalt oxide (PdCoO₂);
a film deposition step of forming a thin film by sputtering using the target; and
an annealing step of heat-treating the thin film.

A method for producing a delafossite-type oxide thin film according to the present disclosure to achieve the above object comprises:
a film deposition step of forming a thin film by sputtering using a target made of a delafossite-type oxide of palladium cobalt oxide (PdCoO₂), palladium chromium oxide (PdCrO₂), palladium rhodium oxide (PdRhO₂), or platinum cobalt oxide (PtCoO₂); and
an annealing step of heat-treating the thin film.

### Advantageous Effect

A palladium cobalt oxide thin film, a delafossite-type oxide thin film, a Schottky electrode having a delafossite-type oxide thin film, a method for producing a palladium cobalt oxide thin film, and a method for producing a delafossite-type oxide thin film can be provided.

### BRIEF DESCRIPTION OF THE DRAWINGS

In the accompanying drawings:

FIG. 1 is an AFM topographic image of a PdCoO₂ thin film according to Example 1;

FIG. 2 is a graph indicating the evaluation result of the roughness of the PdCoO₂ thin film surface along line M in FIG. 1;

FIG. 3 is an X-ray diffraction pattern of a PdCoO₂ thin film immediately after the formation by sputtering in Example 1;

FIG. 4 is a STEM image of the PdCoO₂ thin film in Example 1;

FIG. 5 is an X-ray diffraction pattern of the PdCoO₂ thin film in Example 1; and

FIG. 6 is a graph indicating the temperature dependence of the electrical resistivity of the PdCoO₂ thin film in Example 1.

### DETAILED DESCRIPTION

A palladium cobalt oxide thin film, a delafossite-type oxide thin film, a Schottky electrode having a delafossite-type oxide thin film, a method for producing a palladium cobalt oxide thin film, and a delafossite-type oxide thin film according to an embodiment of the present disclosure will be described with reference to the drawings.

The delafossite-type oxide thin film according to the present embodiment is a delafossite-type oxide thin film of palladium cobalt oxide (PdCoO₂), palladium chromium oxide (PdCrO₂), palladium rhodium oxide (PdRhO₂), or platinum cobalt oxide (PtCoO₂) having a delafossite-type crystal structure. In the following, a palladium cobalt oxide thin film (PdCoO₂ thin film, hereinafter sometimes simply referred to as “oxide thin film”), that is, a thin film made of palladium cobalt oxide having a delafossite-type crystal structure, will be exemplified and described as an example of the delafossite-type oxide thin film according to the present embodiment. The following description similarly applies when palladium cobalt oxide having a delafossite-type crystal structure is replaced with palladium chromium oxide, palladium rhodium oxide, or platinum cobalt oxide, each also having a delafossite-type crystal structure. Specifically, palladium cobalt oxide is represented by the general formula ABO₂, where A is Pd and B is Co. Therefore, for the description regarding the palladium chromium oxide thin film, palladium rhodium oxide thin film, or platinum cobalt oxide thin film and their production methods, the elements Pd and Co in the description of the palladium cobalt oxide thin film and their production method (including descriptions related to the precursors and raw materials of palladium cobalt oxide) can simply be replaced by the corresponding elements A and B for palladium chromium oxide, palladium rhodium oxide, or platinum cobalt oxide.

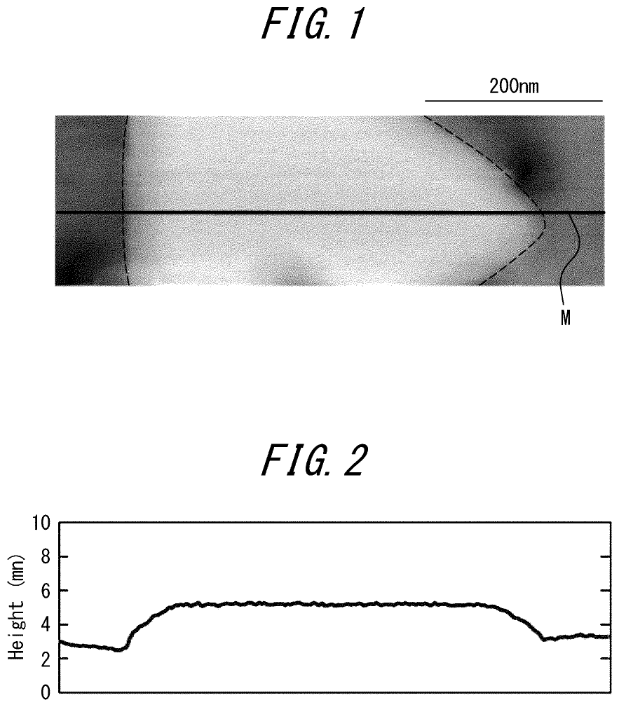

FIG. 1 illustrates one example of an AFM topographic image of an oxide thin film according to the present embodiment. FIG. 2 illustrates the evaluation result of the roughness of the oxide thin film, measured along the line M in the AFM topographic image in FIG. 1. It should be noted that the evaluation result of the roughness illustrated in FIG. 2 indicates the height of the roughness measured along the line M in FIG. 1. As illustrated in FIGS. 1 and 2, the width (or grain width) of the PdCoO₂ crystals in the thin film according to the present embodiment is 100 nm or more and 1000 nm or less. Considering manufacturability of oxide thin films, it is desirable that the width of the PdCoO₂ crystals in the film is 200 nm or more and 500 nm or less. Additionally, the oxide thin film has a thickness greater than the critical film thickness (0.59 nm, the critical film thickness is defined as the film thickness of a layered structure where a single Pd (A) layer and a single CoO₂ (BO₂) layer are stacked), and the roughness value in the thickness direction is 4 nm or less (see FIG. 2). In FIG. 1, the area surrounded by the dashed lines (appearing white in the image) represents a palladium cobalt oxide crystal. Hereinafter, palladium cobalt oxide may be referred to simply as PdCoO₂. The critical film thickness of palladium chromium oxide, palladium rhodium oxide, and platinum cobalt oxide is 0.60 nm, 0.60 nm, and 0.59 nm, respectively.

As illustrated in FIGS. 1 and 2, the oxide thin film according to the present embodiment has larger crystal widths (i.e., larger domain sizes) of palladium cobalt oxide, thereby resulting in higher electrical conductivity compared to conventional palladium cobalt oxide thin films. This makes it suitable for applications such as Schottky electrodes for power devices.

As one example, the oxide thin film according to the present embodiment can be produced by a production method that includes a target production step of firing a mixed powder of palladium chloride (PdCl₂) powder, palladium (Pd) powder, and lithium cobalt oxide (LiCoO₂) powder to produce a PdCoO₂ target; a film deposition step of forming a thin film by sputtering using this target; and an annealing step of heat-treating the formed thin film.

The target production step is the step of producing a PdCoO₂ target to be used in the film deposition step. Before conducting the target production step, a mixing step is initially performed wherein powders of palladium chloride (PdCl₂), palladium (Pd), and lithium cobalt oxide (LiCoO₂) are mixed to form a mixed powder. In the target production step, the mixed powder is fired, and sintered and molded, if required, to produce a PdCoO₂ target.

During the firing of the above-described mixed powder, cations are exchanged according to the reaction shown in the following formula (a), resulting in the synthesis of PdCoO₂ (so-called cation exchange reaction method).

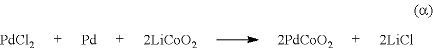

The particle size of the PdCl₂ powder, Pd powder, and LiCoO₂ powder used to produce the mixed powder may be, for example, about a few micrometers to around 100 μm, as measured in images observed under an SEM.

The firing in the target production step is performed at a firing temperature of 500° C. or higher and 900° C. or lower. Preferably, the firing in the target production step is performed at 550° C. or higher and 800° C. or lower. Firing at such firing temperatures allows for the production of PdCoO₂ in powder form while improving the yield. Furthermore, in the target production step, it is desirable to carry out the firing such that the particle size of the fired PdCoO₂ is 0.1 μm or more and 50 μm or less. The particle size of the fired PdCoO₂ powder is 0.1 μm or more and 30 μm or less, as measured in an image observed under an SEM. The particle size of the fired PdCoO₂ powder as described above enhances the tightness of the target after molding, which will be described later, thereby improving the handleability of the target.

The firing in the target production step may be performed under reduced pressure, at atmospheric pressure, or in a high oxygen partial pressure environment. When the firing is performed under reduced pressure, it may be conducted under a reduced pressure of 750 mTorr in an Ar atmosphere, for example. Performing the firing in a high oxygen partial pressure environment may sometimes suppress the decomposition of the fired powder into Pd or CoOx (where x is a positive value).

The above-described target production step can produce a target of PdCoO₂ with relatively high purity.

The target production step may comprise conducting a molding step after the above-described firing to further sinter and mold the fired powder into a disk shape. In the molding step, the fired powder may be sintered while applying a pressure of 30 MPa or higher and 70 MPa or lower at a temperature of 550° C. or higher and 800° C. or lower. Preferably, in the molding step, the fired powder is sintered while applying a pressure of 45 MPa or higher and 55 MPa or lower at a temperature of 650° C. or higher and 750° C. or lower. This can produce a disk-shaped target with good handleability.

In the target production step, the PdCoO₂ obtained by firing may be molded into a target for sputtering. For example, the above-described method for producing a target may not require pulverization of the synthesized PdCoO₂ or additional molding.

The target production step may comprise performing ethanol washing and acid washing of the fired powder after firing. Ethanol washing and acid washing of the fired powder can remove lithium chloride and other impurities. Ethanol washing removes lithium chloride, while acid washing removes unreacted Pd powder (metal palladium). Nitric acid (e.g., with a concentration of 60 weight %) may be used for acid washing, for example.

The target production step may comprise pulverizing the fired powder as necessary to adjust the particle size of the fired powder. For example, adjusting the particle size of the fired powder to the order of several micrometers may improve the tightness of the target after molding as described later.

The film deposition step is a step of forming a PdCoO₂ thin film using the target produced in the target production step by sputtering.

One example of preferred sputtering in the film deposition step is RF sputtering where a radio frequency alternating voltage is applied to the target and the chamber housing the target.

The sputtering conditions for forming a PdCoO₂ thin film using RF sputtering in the film deposition step are as follows. The oxygen partial pressure during sputtering is 50 mTorr or higher and 250 mTorr or lower, preferably 80 mTorr or higher and 120 mTorr or lower. The substrate temperature during sputtering is 500° C. or higher and 800° C. or lower, preferably 550° C. or higher and 700° C. or lower. As a substrate for forming the PdCoO₂ thin film, an Al₂O₃ (0001) substrate, i.e., a sapphire substrate (using the (0001) plane), can be used, for example.

By conducting the film deposition step as described above, a thin film with large crystal grains of PdCoO₂ can be obtained even when a film with a thickness of 20 nm or less is formed, for example. Additionally, this thin film has a high flatness, the crystals are oriented along the c-axis, and the crystallinity is high.

The thin film formed in the film deposition step is subsequently subjected to an annealing step for heat treatment. This heat treatment allows for the production of a PdCoO₂ thin film that contains no metal palladium and has a low electrical resistivity. Furthermore, this PdCoO₂ thin film exhibits high crystallinity.

In the present embodiment, the phrase “not containing metal palladium or tricobalt tetroxide (Co₃O₄) in the PdCoO₂ thin film” refers to the following. For example, when the intensities of the X-ray diffraction peaks corresponding to the diffraction angle of the (111) plane of metal palladium (40.1°) or the diffraction angle corresponding to the (222) plane of Co₃O₄ (about) 38.6°, observed by X-ray diffraction (XRD) is compared with the intensity of the X-ray diffraction peak corresponding to the diffraction angle of the (0006) plane of PdCoO₂ (30.2°), the intensities of the peaks corresponding to the diffraction angles of the (111) plane of metal palladium and the (222) plane of Co₃O₄ (about) 38.6° are 1/100 or less of the intensity of the X-ray diffraction peak corresponding to the (0006) plane of PdCoO₂.

The heat treatment in the annealing step is conducted at a temperature of 600° C. or higher and 800° C. or lower, preferably 650° C. or higher and 700° C. or lower. This allows for the appropriate production of a PdCoO₂ thin film that has a low electrical resistivity and does not contain metal palladium.

The oxide thin film according to the present embodiment is preferably formed to 1 nm or more and 20 nm or less. Such an oxide thin film is suitable for use as a Schottky electrode.

In the above description, the delafossite-type oxide thin film, the Schottky electrode having a delafossite-type oxide thin film, and the method for producing a delafossite-type oxide thin film have been described using the palladium cobalt oxide thin film as an example. However, as mentioned in the introduction, the description using the palladium cobalt oxide thin film as an example also applies similarly to a palladium chromium oxide thin film, a palladium rhodium oxide thin film, or a platinum cobalt oxide thin film. Furthermore, the methods for producing these thin films and Schottky electrodes including these thin films are similar to the method for producing a palladium cobalt oxide thin film and the Schottky electrode including the palladium cobalt oxide thin film.

### EXAMPLES

### Example 1

A palladium cobalt oxide thin film according to Example 1 was produced as follows.

Powdered PdCl₂ (manufactured by Tanaka Precious Metals Co. Ltd., Pd chloride crystal), powdered Pd (manufactured by Tanaka Precious Metals Co. Ltd., Pd powder with a Pd purity higher than 99.9%), and powdered LiCoO₂ (manufactured by Sigma-Aldrich, lithium cobalt oxide (III)) were weighed out 8.99 g, 5.39 g, and 9.92 g, respectively. They were mixed for 10 minutes in a mortar to obtain a mixed powder. The particle size of the LiCoO₂ powder was in the range of about several micrometers to a dozen or so micrometers, as measured in images observed under an SEM.

Next, the mixed powder was vacuum-sealed (at about 10⁻⁵ Torr) in a quartz tube, and the quartz tube was placed in a retention tube made of mullite. The retention tube was placed in a firing furnace equipped with a core tube made of mullite. The core tube of the firing furnace was controlled to maintain a temperature of 800° C., and the mixture was fired for 48 hours. The powder containing PdCoO₂ was then recovered from the quartz tube.

The powder containing PdCoO₂ was washed with ethanol to remove lithium chloride (ethanol washing), followed by washing with nitric acid (at a concentration of 60 weight %) to remove unreacted Pd (acid washing), to yield PdCoO₂ powder. The recovered PdCoO₂ powder weighed 17.58 g. In the ethanol washing, the powder containing PdCoO₂ was stirred in ethanol for one hour. In the acid washing, the powder was stirred in nitric acid for four hours. The particle size of the PdCoO₂ powder, as measured in an image observed under an SEM, approximately ranged from about 1 μm to 50 μm.

Next, the PdCoO₂ powder was packed into a molding die and sintered by hot-press sintering under pressure to produce a processed disk-shaped target. The pressure during sintering (the pressure applied to the powder) was set to 50 MPa. The temperature inside the sintering furnace during sintering was maintained at 700° C. for 60 minutes. The sintering furnace was kept under a vacuum atmosphere.

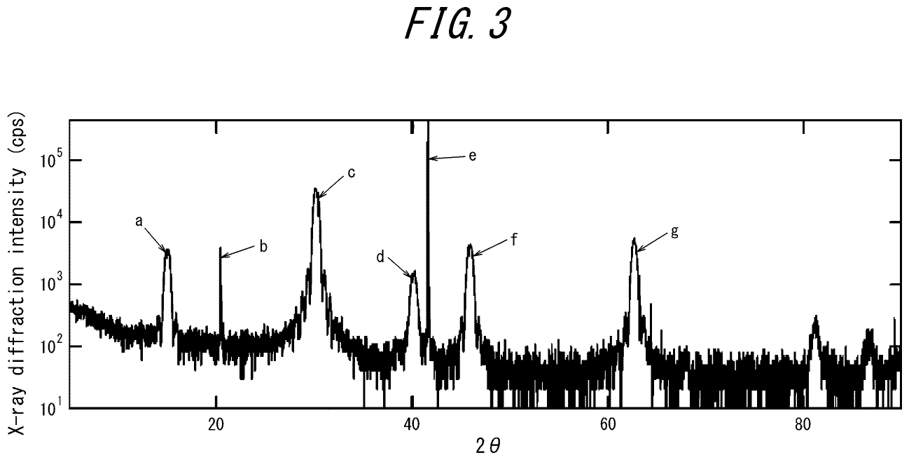

Then, a PdCoO₂ thin film was formed by RF sputtering using the disk-shaped target obtained as described above. Considering handling in the sputtering apparatus, the target was affixed to a copper backing plate (with a diameter of 50.8 mm and a thickness of 2 mm) and placed inside the chamber of the sputtering apparatus. The substrate used to form a thin film was an Al₂O₃ (0001) substrate (hereinafter referred to simply as the substrate). Upon sputtering, the chamber atmosphere was set to an oxygen-to-argon ratio of 2:1 at a pressure of 150 m Torr (with an oxygen partial pressure in the chamber of 100 mTorr), and the substrate temperature was set to 700° C. The RF power output was set to 100 W, and the frequency to 13.56 MHz. The target film thickness of the PdCoO₂ thin film was 15 nm. The PdCoO₂ thin film formed by sputtering was evaluated by X-ray diffraction. FIG. 3 illustrates the X-ray diffraction pattern of the thin film immediately after formation by sputtering. FIG. 3 will be discussed later.

The substrate having the PdCoO₂ thin film formed thereon as described above was placed in a heating furnace set at 800° C., heat-treated at atmospheric pressure for 12 hours, and then removed from the furnace to yield a palladium cobalt oxide thin film according to Example 1. In the following description, the term “thin film” refers to the thin film after heat treatment.

The film thickness of the thin film was measured, the surface flatness was observed by AFM, and the thin film was subjected to X-ray diffraction and a measurement of the electrical resistivity.

The film thickness of the thin film was 15 nm. The interval of interference fringes near the PdCoO₂ (0006) diffraction point was measured using X-ray diffraction, and the film thickness was determined based on the measurement.

The observation results of the surface morphology of the thin film by AFM (AFM topographic image) are as discussed previously with reference to FIGS. 1 and 2 described above. In the thin film, the width of PdCoO₂ crystals in the film was about 400 nm. Additionally, the thin film has a height of the crystals and a roughness value (peak top difference) in the thickness direction (height direction) on the film surface of about 3 nm. The PdCoO₂ crystals in the film had a triangular shape.

The AFM topographic image illustrated in FIG. 1 was captured using an atomic force microscope model AFM5000II manufactured by Hitachi High-Tech Corporation in dynamic force mode (DFM).

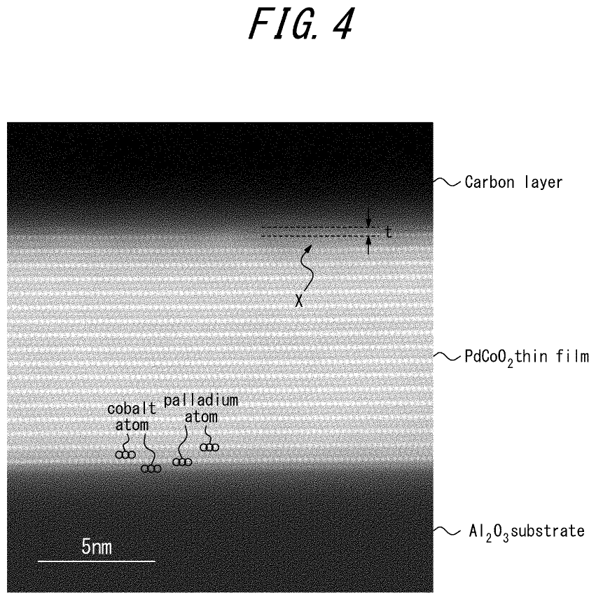

FIG. 4 illustrates a high-angle annular dark-field scanning TEM (HAADF-STEM) image (hereinafter referred to as STEM image) of a cross-section of the thin film. This STEM image was captured using Titan Cubed manufactured by FEI Company at an accelerating voltage of 300 kV. In FIG. 4, the carbon film in the cross-section originated from the covering of the cross-section of the thin film for the TEM observation, not from the thin film. In the cross-sectional part of the PdCoO₂ thin film illustrated in FIG. 4, the Pd and Co atoms are arranged in a delafossite-type structure. On the surface of the PdCoO₂ thin film (the surface opposite to the Al₂O₃ substrate and facing the carbon film), depressions (e.g., the X-region in FIG. 4) can be observed. The roughness value in the thickness direction of the thin film such as this depression (e.g., the depth t of the depression in the X-region) is well below 4 nm.

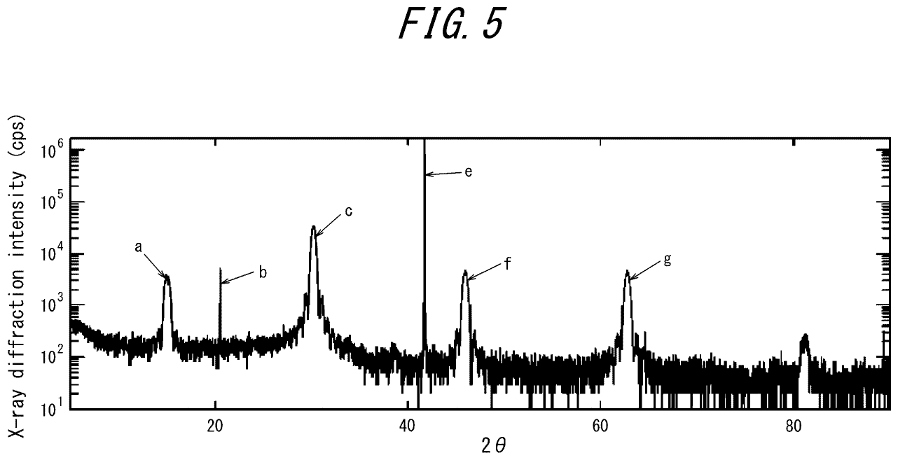

Next, the thin film was evaluated by X-ray diffraction. FIG. 5 illustrates the X-ray diffraction pattern of the thin film in Example 1.

As described above, FIG. 3 illustrates the X-ray diffraction pattern of the thin film immediately after formation by sputtering in Example 1. As illustrated in FIG. 3, in the X-ray diffraction pattern of the thin film immediately after formation by sputtering, peaks indicated by symbols a to g are observed in FIG. 3. These peaks correspond in sequence to the following: symbol a: PdCoO₂ (0003), symbol b: sapphire substrate, symbol c: PdCoO₂ (0006), symbol d: Pd (111), symbol e: sapphire substrate, and symbol f: PdCoO₂ (0009). In the thin film immediately after formation by sputtering, no peaks related to other impurities were detected.

Similarly to FIG. 3, in the X-ray diffraction pattern of the thin film in Example 1 illustrated in FIG. 5, peaks denoted by symbol a: PdCoO₂ (0003), symbol b: sapphire substrate, symbol c: PdCoO₂ (0006), symbol e: sapphire substrate, and symbol f: PdCoO₂ (0009) were observed. However, in FIG. 5, the intensities of the diffracted X-ray at the diffraction angle corresponding to Pd (111) (about 40.1°) and the diffraction angle corresponding to Co₃O₄ (222) (about) 38.6° were at least less than 1/100 of the intensity of the X-ray diffraction peak corresponding to PdCoO₂ (0006), and the diffraction X-ray peaks could not be indistinguishable from the baseline. This suggests that the thin film contains neither metal palladium nor tricobalt tetroxide to the extent detectable by X-ray diffraction. Moreover, no peaks related to other impurities were observed in the thin film in Example 1.

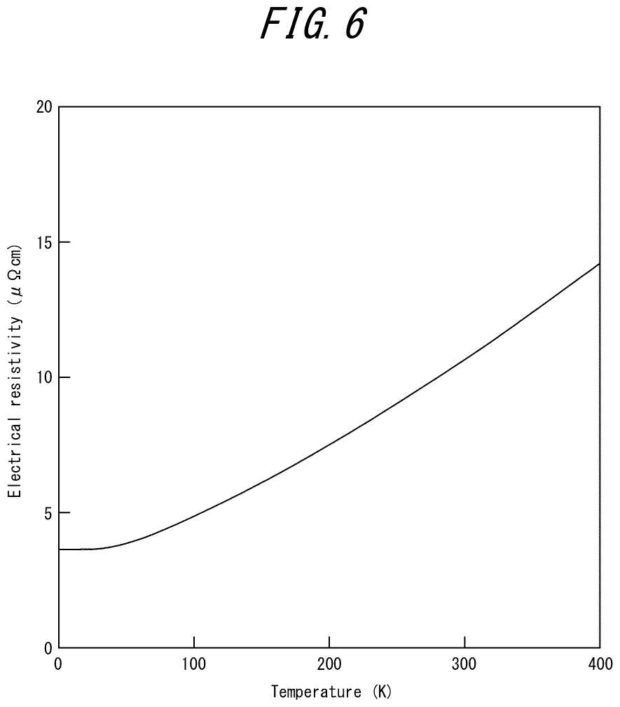

FIG. 6 illustrates a graph illustrating the temperature dependence of the electrical resistivity of this thin film. The graph in FIG. 6 shows the value of electrical resistivity measured while the temperature of the thin film was raised from absolute temperatures of 2 K to 400 K. The electrical resistivity was measured as follows. Specifically, Au (gold) wires were bonded by In (indium) crimping, and the temperature dependence of sheet resistance was measured by the DC four-terminal method. The volume resistivity (μΩ·cm) was calculated based on the film thickness (about 15 nm) obtained by the above-described X-ray diffraction.

As illustrated in FIG. 6, the electrical resistivity of the thin film in Example 1 from absolute temperatures of 2 K to 150 K is 3 μΩcm or higher and 6 μΩcm or lower.

Additionally, the electrical resistivity of the thin film in Example 1 from absolute temperatures of 2 K to 400 K satisfies the following equation (1):

$$R < 0.025 \times T + 5 \qquad ( 1 )$$

where R (μΩcm) represents the electrical resistivity and T (K) represents the absolute temperature.

As described above, the thin film in Example 1 demonstrated low electrical resistivity and high electrical conductivity even with a reduced film thickness. Given that the electrical resistivity of platinum is 9.81 μΩcm at an absolute temperature of 273 K and 13.6 μΩcm at 373 K, the thin film in Example 1 exhibited high electrical conductivity comparable to that of elemental metals even with a small film thickness of 20 nm or less, such as 15 nm. Therefore, the thin film is considered highly suitable for Schottky electrode applications, for example, when combined with gallium oxide. Such a high electrical conductivity observed in the thin film in Example 1 is believed to be attributable to the fact that, as indicated in the surface morphology results in FIGS. 1 and 2, the grain sizes of the PdCoO₂ crystals in the thin film in Example 1 were larger compared to those in PdCoO₂ thin films produced by conventional methods. The increased grain sizes reduced the boundaries between particles, thereby decreasing the inter-boundary resistance, which likely contributed to the high electrical conductivity.

Additionally, the thin film in Example 1 did not contain metal palladium or other impurities, and it is considered to be produced with high reproducibility. Moreover, the lack of impurities ensures that when used in Schottky electrode applications in combination with materials such as gallium oxide, the thin film can achieve both heat resistance and reliability even in high-power applications, for example, without compromising the high thermal stability and chemical resistance of gallium oxide.

Pulsed-laser deposition disclosed in NPLs 1 to 3 is not well-suited for forming large-area thin films. As pointed out in NPL 2, forming large-area palladium cobalt oxide thin films on an industrial scale with pulsed-laser deposition is challenging. However, the method for producing a palladium cobalt oxide thin film according to the present embodiment uses sputtering for the deposition of PdCoO₂ thin films, enabling the easy formation of large-area palladium cobalt oxide thin films and making the films suitable for industrial-scale production.

Additionally, in comparison to the formation method of palladium cobalt oxide thin films by pulsed-laser deposition disclosed in NPLs 1 to 3, the method for producing a palladium cobalt oxide thin film according to the present embodiment does not require the use of two targets with different compositions, as is necessary for pulsed-laser deposition disclosed in NPLs 1 to 3. Instead, it allows for the formation of palladium cobalt oxide thin films using only a single target. Therefore, the production method according to the embodiment simplifies the production of thin films. Furthermore, when two targets with different compositions are used, it becomes challenging to consistently form palladium cobalt oxide thin films with the same composition or crystal structure, resulting in lower reproducibility in production. However, with the production method according to the present embodiment, palladium cobalt oxide thin films can be produced using only a single target, making it easier to consistently form palladium cobalt oxide thin films with the same composition or crystal structure and thereby increasing reproducibility in production.

Considering the common properties of bulk single crystals of palladium cobalt oxide, palladium chromium oxide, palladium rhodium oxide, and platinum cobalt oxide as delafossite-type oxides, as well as the common properties among palladium, platinum, chromium, cobalt, and rhodium, it is believed that the characteristics demonstrated in the above example associated with the palladium cobalt oxide thin film, the Schottky electrode having a palladium cobalt oxide thin film, and the method for producing a palladium cobalt oxide thin film are, as a matter of fact, also applicable to delafossite-type oxides other than palladium cobalt oxide, namely, palladium chromium oxide, palladium rhodium oxide, and platinum cobalt oxide.

As described above, a palladium cobalt oxide thin film, a delafossite-type oxide thin film, a Schottky electrode having a delafossite-type oxide thin film, a method for producing a palladium cobalt oxide thin film, and a method for producing a delafossite-type oxide thin film can be provided.

It should be noted that the embodiment disclosed in this specification is illustrative, and the embodiment of the present disclosure is not limited thereto. Modifications may be appropriately made within the scope that does not deviate from the object of the present disclosure.

### INDUSTRIAL APPLICABILITY

The present disclosure is applicable to palladium cobalt oxide thin films, delafossite-type oxide thin films, Schottky electrodes having delafossite-type oxide thin films, methods for producing palladium cobalt oxide thin films, and methods for producing delafossite-type oxide thin films.

1. A palladium cobalt oxide thin film, wherein a crystal width in the film is 100 nm or more and 1000 nm or less, a film thickness is greater than a critical film thickness, and a roughness value in a thickness direction is 4 nm or less.

2. The palladium cobalt oxide thin film according to claim 1, wherein an electrical resistivity is 6 μΩcm or less at absolute temperatures from 2 K to 150 K, and
the electrical resistivity at absolute temperatures from 150 K to 400 K satisfies the following formula (1):
$$R < 0.025 \times T + 5 \qquad ( 1 )$$
where the absolute temperature (K) is represented by T (K) and the electrical resistivity is represented by R (μΩcm).

3. The palladium cobalt oxide thin film according to claim 1, wherein palladium cobalt oxide thin film does not contain metal palladium crystals or tricobalt tetroxide.

4. The palladium cobalt oxide thin film according to claim 1, wherein the film thickness is 20 nm or less.

5. A delafossite-type oxide thin film comprising palladium chromium oxide (PdCrO₂), palladium rhodium oxide (PdRhO₂), or platinum cobalt oxide (PtCoO₂) having a delafossite-type crystal structure,
wherein a crystal width in the film is 100 nm or more and 1000 nm or less,
a film thickness is greater than a critical film thickness, and a roughness value in a thickness direction is 4 nm or less.

6. A Schottky electrode comprising a delafossite-type oxide thin film of palladium cobalt oxide (PdCoO₂), palladium chromium oxide (PdCrO₂), palladium rhodium oxide (PdRhO₂), or platinum cobalt oxide (PtCoO₂), wherein a crystal grain size in the film is 100 nm or more and 1000 nm or less, a film thickness is greater than a critical film thickness, and a roughness value in a thickness direction is 4 nm or less.

7. A method for producing a palladium cobalt oxide thin film comprising:
a target production step of firing a mixed powder of palladium chloride (PdCl₂), palladium (Pd), and lithium cobalt oxide (LiCoO₂) to produce a target of palladium cobalt oxide (PdCoO₂);
a film deposition step of forming a thin film by sputtering using the target; and
an annealing step of heat-treating the thin film.

8. The method for producing a palladium cobalt oxide thin film according to claim 7, wherein the annealing step comprises heat-treating the thin film at a temperature from 600° C. to 800° C.

9. A method of forming a delafossite-type oxide thin film comprising:
a film deposition step of forming a thin film by sputtering using a target made of a delafossite-type oxide of palladium cobalt oxide (PdCoO₂), palladium chromium oxide (PdCrO₂), palladium rhodium oxide (PdRhO₂), or platinum cobalt oxide (PtCoO₂); and
an annealing step of heat-treating the thin film.
